(19) United States
(12) Patent Application Publication
(10) Pub. No.: US 2023/0324465 A1
(43) Pub. Date: Oct. 12, 2023

(54) METHOD FOR CALIBRATING A PLURALITY OF CURRENT SENSORS, BATTERY SYSTEM

(71) Applicant: Robert Bosch GmbH, Stuttgart (DE)

(72) Inventor: Mathis Wolf, Kornwestheim (DE)

(21) Appl. No.: 18/186,317

(22) Filed: Mar. 20, 2023

(30) Foreign Application Priority Data
Mar. 21, 2022 (DE) 10 2022 202 721.3

(51) Int. Cl. G01R 19/32; G01R 31/364; H01M 10/48; G01R 31/3828; G01R 19/00

(52) U.S. Cl. CPC G01R 31/3828; G01R 19/0092; G01R 19/32; G01R 31/364; H01M 10/482; H01M 2220/20

(57) ABSTRACT

A method for calibrating a plurality of current sensors connected in series. The method include determining a temperature difference between the current sensors; sensing temperature values and current values of the respective current sensors at different temperatures and currents; calculating averaged current values of two current sensors based on the current measured values sensed by the respective current sensors; calculating a current regression area for the respective current sensors through measurement points that are dependent on the temperature of the respective current sensors and the deviation of the current values sensed by the respective current sensors relative to one another; and calculating a TCR regression curve or a TCR regression area for the respective current sensors based on a deviation and an intersection curve of the respective current regression areas relative to one another and/or relative to an averaged current regression area and a temperature difference between the current sensors.

### BACKGROUND OF THE INVENTION

The invention relates to a method for calibrating a plurality of current sensors connected in series.

The invention furthermore relates to a battery system and a vehicle.

It is becoming apparent that electrically driven motor vehicles will increasingly be used in the future. Such electrically driven motor vehicles, such as electric vehicles and hybrid vehicles, each comprise an electrical energy supply system comprising at least one battery system.

For monitoring the electrical energy supply system, a supply current of the electrical energy supply system is determined. This determination of the supply current can take place by means of a current measuring device, which comprises, for example, a plurality of current sensors used in the electrical energy supply system or battery system, such as current measuring resistors, also respectively referred to as a shunt, and contactless current sensors, such as Hall sensors, as well as measurement electronics.

The highly precise measurement plays an increasingly important role in this regard, e.g., for range optimization in order to increase the effectively usable range of a battery system, Vehicle2Grid (V2G, from the vehicle to the grid) for accurate accounting when charging or feeding into the power grid, a more precise determination of the state of health (SOH) in order to more accurately determine the age and extend the service life of a battery system, and a rapid charging in order to increase the usable rapid charging range of a battery system and thus to charge more quickly.

However, the current sensors and the measurement electronics may deviate over the temperature and lifetime. The following calibration methods are typically used for the calibration: the initial drift of the current sensors can be calibrated at the factory and/or during production and the initial offset of the measurement electronics can be calibrated at a current flow of 0A.

Document DE 10 2017 212 960 A1 describes a calibration method for a current measuring system for measuring an electrical current of an electrochemical energy storage system. The calibration determines a calibration current by means of a calibration resistor and compares it to the electrical current determined based on a measured voltage. At least one correction factor is determined based on a difference between the calibration current and the electrical current of the energy store.

Document DE 10 2016 202 498 A1 describes a measuring resistor calibration device comprising a measurement connection, a reference resistor, a reference connection and an analog-to-digital converter. DE 10 2016 202 498 A1 also discloses a method for calibrating a measuring resistor.

Document DE 699 33 553 T2 relates to electronic battery testing devices used for testing the storage battery. DE 699 33 553 T2 discloses a calibration circuit arrangement. The calibration circuit arrangement comprises a shunt whose conductivity is measured. The measured value is compared to a stored calibrated standard.

### SUMMARY OF THE INVENTION

A method for calibrating a plurality of current sensors connected in series is proposed. The term “series connection of current sensors” in the sense of the invention is understood to mean that the current sensors, such as two current measuring resistors or one current measuring resistor and one Hall sensor, measure the same current. Accordingly, the term “parallel connection of the current sensors” in the sense of the invention is understood to mean that the current sensors measure different currents. Advantageously, all current sensors that are connected in series and respectively have a temperature-dependent error curve, such as a TCR (temperature coefficient of resistance) curve in the case of a resistor, can be calibrated. However, in the sense of the invention, the meaning of the term “TCR” is extended or generalized. The term “TCR” in the sense of the invention is understood to mean a temperature-dependent error. For example, for a current measuring resistor, a TCR curve is to be understood as a temperature-dependent error curve. This temperature-dependent error or measurement error of a current sensor, such as a Hall sensor, could however also be current-dependent. This is referred to as a TCR area.

Preferably, a temperature sensor, such as an NTC (negative temperature coefficient) resistor or a PTC (positive temperature coefficient) resistor, is respectively provided for the current sensors. The temperature sensors are each arranged on an associated current sensor.

When performing the method proposed according to the invention, a temperature difference is determined between the current sensors. For example, the temperature difference may be automatically generated during operation due to different resistance values of the current sensors. However, the temperature difference may also be artificially generated after operation by a current flowing only through one current measuring resistor. After a certain period of time, the current measuring resistors are connected in series. It is also conceivable that a temperature difference is generated by heating a current sensor by an electrical consumer, such as a heating device or a battery of a vehicle. It is also possible to generate a temperature difference by the current sensors being mounted at different positions of a cooling circuit. The temperature difference between the current sensors may be different.

Temperature values and current values of the respective current sensors are subsequently sensed at different temperatures and currents.

Thereafter, averaged current values are calculated based on the current values sensed by the respective current sensors. The averaged current values are stored as values with the respective temperature of the current sensors.

A current regression area for the respective current sensors is subsequently respectively calculated through measurement points that are dependent on the temperature of the respective current sensors, optionally a current average of the current values sensed by the respective current sensors, and the deviation of the current values sensed by the respective current sensors relative to one another. As a result, relative deviations of the respective current sensors relative to one another are known.

Following the calculation of the current regression area, an averaged current regression area may also be formed, which comprises the averaged current values as a function of the respective temperature of the current sensors and the TCR regression curves to be calculated. The averaged current regression area is exactly between the current regression areas of the current sensors and is also formed at different temperatures.

It is also possible to calculate a current regression curve corresponding to the TCR curve. This does not contain any current values and therefore consists only of a point with a pair of values from the temperature and the deviation of the current values sensed by the respective current sensors relative to one another. Since the TCR curves of the respective current sensors can be determined particularly accurately at higher currents, and some current sensor technologies do not behave linearly over the current measurement range, only current regression areas are hereinafter referred to. By including the current values, the TCR curves can therefore be determined more accurately, and depending on the current. In the case of, for example, current measuring resistors, the absolute errors as well as the noise and other inaccuracies of the measuring device are negligible at larger currents.

If the current regression area is projected onto an X-Y plane of a three-dimensional coordinate system, i.e., the Z coordinate (the current value) is set equal to zero, and a regression is performed through the projected points in the X-Y plane, the TCR curve is created. Since, at larger currents, the measurement points of the current measuring resistors are more accurate, they may be weighted higher or small currents may be ignored. The current values are therefore not necessarily needed for certain current sensor technologies where non-linearity over the current measurement range can be neglected (such as current measuring resistors).

Thereafter, a TCR regression curve or a current-dependent TCR regression area is calculated for the respective current sensors based on a deviation of the respective regression areas between the current sensors. By determining the intersection curve of both regression areas, a statement about the absolute deviation can be made. For example, the statement may be made assuming that the deviation of the resistance values of the respective current sensors at a particular temperature, such as 20° C., is zero. The TCR regression curves intersect there. In some circumstances, it may be sufficient to calculate a single correction factor per current sensor by means of different temperature values at the respective current sensors. In this case, the TCR regression curve becomes a TCR regression line. The correction factor corresponds to the slope of the TCR regression line. In other words, an nth-order regression, such as a polynomial regression, or a regression area, such as a multiple linear regression, is not necessary in this case.

Subsequently, quality characteristics of the respective current sensors may be evaluated. The quality characteristics are not satisfied if current values are outside the overall tolerance range, for example. In the process, the anomalies of the current sensors may be diagnosed, for example, if the current regression area of a current sensor is outside of a tolerance range or if the measured values suddenly deviate from those expected, and if necessary, countermeasures, such as an inspection in the workshop and/or a performance restriction, may be initiated.

When performing the method proposed according to the invention, limit values or boundary conditions are considered as follows.

If at temperatures not equal to 20° C., the current regression areas of the current sensors are at a maximum distance from one another but are still in a valid overall tolerance range, a mean value is formed from measured values of the current sensors. The expected overall tolerance, which comprises the tolerance of current sensors and measurement electronics as well as, where appropriate, also temperature sensor tolerance or time-related temperature measurement errors, is close to zero.

If the current regression areas of the current sensors are on top of one another, the current sensors have the same temperature-related deviation or the same TCR curve. A temperature difference between the current sensors helps determine the relative deviation of the current sensors. If the relative deviation is equal to zero, the current sensors do not have a temperature-related deviation, i.e., for example, the resistance-value change rate of the current measuring resistors is at zero over the entire temperature range.

In order to minimize the effects of the inertia of the temperature measurement, some seconds before and thereafter, the temperature measured values along with the associated current measured values of the respective current sensors can be included with a weighting. for example. For example, a weighted filter may be used in the time range.

Preferably, timestamps of the temperature and current measurements are captured at different temperatures and currents. Thus, temperature-related deviations changing over the lifetime, or errors, can be compensated even if, for example, the TCR curve of a current sensor changes over the lifetime.

Preferably, an individual TCR tolerance range, in which the individual temperature-dependent error or the TCR regression curve to be calculated of the respective current sensors lies, is calculated for the respective current sensors. In the process, this TCR tolerance range may be calculated by means of the TCR regression curve and the errors of the measuring device in order to generate individual tolerance ranges for each current sensor.

Preferably, a conversion table, also referred to as a lookup table (LUT), is created for the current measurements. By means of this conversion table, the current regression areas and thus the TCR regression curves of the calibrated current sensors can be inter- and extrapolated. Based on this conversion table, one current sensor may be calibrated with another current sensor. For example, the current sensors operate in a temperature range of 30° C. to 60° C. This allows a tendency to be calculated as to whether the TCR curve has a positive or negative slope.

During the creation, the initial values of the respective current sensors, e.g., the default values or predetermined standard values of the current sensors, are first entered into the conversion table.

The sensed temperature values and current values of the respective current sensors are subsequently determined at different temperatures and currents. Timestamps of the acquisitions may be determined at different temperatures and currents. The averaged current values as well as the current regression areas can be calculated in the process. The TCR regression curves can in turn be derived therefrom.

The conversion table and TCR regression curves derived from the current regression areas are then constantly updated. In the process, older values, e.g., of more than 6 months, can automatically be removed from the conversion table and be replaced by newer values.

A plausibility check is furthermore constantly carried out as to whether the temperature-dependent error of the respective current sensors is in the overall tolerance range resulting from adding the tolerance ranges of all components of a current measuring device. If the individual TCR curve is determined, an individual TCR tolerance range, which is a subset of the overall tolerance range, is calculated from the overall tolerance range. In the event of a permanent deviation, countermeasures may be initiated, such as an inspection in the workshop.

In order to avoid having to store too many data, old data acquired based on measurements and/or calculations, are preferably overwritten like in a circular buffer, provided that they contain new or better information, such as measurements at a greater temperature difference, or the timestamp is older than a predetermined number of months. In principle, the TCR regression curves and current regression areas are more accurate if the measurements take place at greater temperature differences, since the error caused by the temperature sensor, such as the thermal inertia of the temperature sensor, is less. If the new measured value point is close to the already calculated current regression area, no new values need to be stored. The calculated current regression areas may change over the lifetime.

In order to save computing power, the method proposed according to the invention may be simplified or may only be carried out in particular circumstances, such as the charging of a battery system with a plurality of current sensors connectable in series, where a greater temperature difference can be artificially generated. A further advantage of performing the method proposed according to the invention when charging the battery system is that the fluctuations in current and temperature are lower since a relatively constant current flows and the temperature changes only slowly as a result. This leads to a lower influence of the measurement inaccuracy of the temperature sensors, which is also caused, for example, by a lower thermal inertia.

Preferably, one of the current sensors is selected as the reference sensor, which is used to calibrate all the other current sensors. Particularly preferably, a current sensor is selected that is more precise than other current sensors. For example, a low-side current measuring resistor may be selected.

Preferably, the quality characteristics of the respective current sensors are evaluated by means of cloud-controlled artificial intelligence. As a result, the anomalies of the current sensors can be more easily diagnosed. The quality characteristics of the current sensors can be evaluated centrally. For example, the quality characteristics of the current sensors of all vehicles in service may be evaluated thereby. In the process, influences in different climate zones, altitudes or of the driving style can be better compared, understood and corrected.

A further aspect of the invention is the provision of a battery system comprising a plurality of current sensors connectable and/or connected in series. The battery system comprises a means, such as a battery management system, that is configured to perform the method proposed according to the invention. Accordingly, features described in the context of the method apply to the battery system, and vice versa, features described in the context of the battery system apply to the method.

The battery system proposed according to the invention may comprise a plurality of battery modules that can be connected in series. The battery modules may comprise one or more battery cells, preferably lithium-ion cells. The plurality of battery cells may be connected in series and/or in parallel. A current sensor for sensing the module current is provided for each battery module. The battery system may operate in a plurality of operating modes. For example, in a first operating mode, the battery modules may be interconnected in series in order to increase the battery voltage, while in a second operating mode, they are interconnected in parallel in order to increase the battery current. The current sensors are connected in series in the first operating mode and in parallel in the second operating mode. The current sensors are each provided with a temperature sensor. By means of the method proposed according to the invention, the current sensors, in particular the TCR curves, can be calibrated.

Preferably, the current sensors are thermally decoupled from one another. For example, this may be achieved by spatially separating the current sensors.

It is conceivable that current measuring resistors are thermally decoupled from one another by the selection of different resistivities, for example. In this case, the current and the different self-heating caused by the current lead to a temperature difference.

However, it is also conceivable that the thermal decoupling is achieved by the selection of different current measurement technologies, such as contactless measurement principles like Hall sensors. By means of external or internal temperature measurement at the Hall sensor, the latter or other contactless current measurement technologies can also be calibrated via the temperature.

It is also possible for two Hall sensors connected in series, for example, to be calibrated by means of the method proposed according to the invention, since they also have a temperature-dependent error that is similar to a TCR curve. It is also conceivable that a combination of Hall sensors and current measuring resistors is used.

Preferably, the current sensors have different resistance values and/or tolerances.

A vehicle is also proposed. The vehicle is configured to perform the method proposed according to the invention, and/or the vehicle comprises the battery system proposed according to the invention.

The method described herein for calibrating a plurality of current sensors may be performed permanently by the required redundancies in a current measuring system or a current measuring device. The method proposed according to the invention may also be used for different measurement principles or different current sensors. For example, Hall sensors connected in series may be calibrated. It is also possible for Hall sensors to be calibrated with current measuring resistors, or vice versa.

The current measurement of a plurality of current sensors while driving and in particular also while charging can be continuously calibrated in order to check the accuracy of the current measuring resistors and, if necessary, to initiate countermeasures. The temperature-related tolerances (shown by TCR curves) of the current sensors may be fully eliminated. As a result, failures can be avoided due to the plausibility check and early detection of erroneous behavior.

If the calibration is not possible while driving due to a low temperature difference, it may, for example, also be performed monthly during charging, e.g., overnight.

The present invention provides an inexpensive solution for measuring the current with high precision over the temperature range by means of a plurality of current sensors.

### BRIEF DESCRIPTION OF THE DRAWINGS

Embodiments of the invention are explained in more detail with reference to the drawings and the following description.

Shown are:

FIG. 1 a schematic representation of a battery system in a first operating mode,

FIG. 2 a schematic representation of the battery system in a second operating mode,

FIG. 3 a schematic representation of a TCR diagram of a current sensor,

FIG. 4 a schematic representation of the use of the TCR diagram to perform the method proposed according to the invention, and

FIG. 5 a schematic representation of a conversion table created when performing the method proposed according to the invention.

### DETAILED DESCRIPTION

In the following description of the embodiments of the invention, identical or similar elements are denoted by identical reference signs, wherein a repeated description of these elements is dispensed with in individual cases. The figures show the subject matter of the invention only schematically.

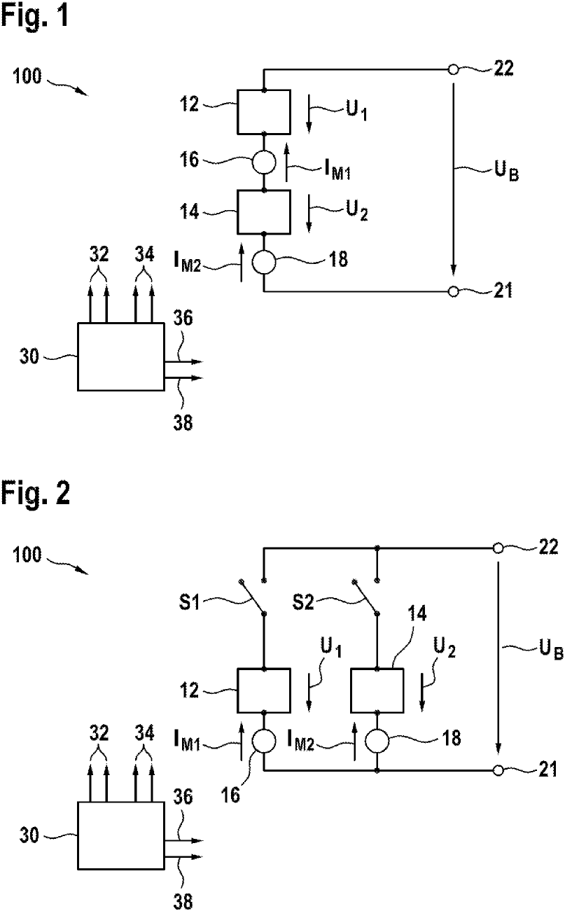

FIG. 1 shows a schematic representation of a battery system 100 operating in a first operating mode, while FIG. 2 shows a schematic representation of the battery system 100 operating in a second operating mode.

The battery system 100 comprises a negative pole 21, a positive pole 22, a first battery module 12 and a second battery module 14. Of course, the battery system 100 may comprise more than two battery modules 12, 14. Usually, all battery modules 12, 14 have an identical structure.

For the first battery module 12, a first current sensor 16 for sensing a first current I_{M1} flowing through the first battery module 12 is provided, while for the second battery module 14, a second current sensor 18 for sensing a second current I_{M2} flowing through the second battery module 14 is provided. For the first and the second current sensor 16, 18, a temperature sensor (not shown here) for measuring the temperature of the respective current sensors 16, 18 is respectively provided. Preferably, the temperature sensors are each designed as an NTC resistor. The two current sensors 16, 18 may each be designed as a current measuring resistor (shunt). However, they may also each be designed as a Hall sensor. It is also conceivable that one of the two current sensors 16, 18 is designed as a current measuring resistor, while the other current sensor is designed as a Hall sensor.

The first battery module 12 has a first module voltage U₁, while the second battery module 14 has a second module voltage U₂. Between the negative pole 21 and the positive pole 22, a battery voltage U_{B} is applied, which can be calculated depending on the interconnection of the battery modules 12, 14.

In the first operating mode of the battery system 100 shown in FIG. 1, the first and the second battery module 12, 14 are connected in series between the negative and the positive pole 21, 22. The first and the second current sensor 16, 18 are also connected in series. The module voltages U₁, U₂ add up to the battery voltage U_{B} in this operating mode. The first and the second current sensor 16, 18 therefore measure the same current.

In the second operating mode of the battery system 100 shown in FIG. 2, the two battery modules 12, 14 are interconnected in parallel to one another between the negative and the positive pole 21, 22. The two current sensors 16, 18 are likewise connected in parallel to one another. In this case, the first battery module 12 can be connected by means of a first switch S1, while the second battery module 14 can be connected by means of a second switch S2. The two battery modules 12, 14 can thus be connected simultaneously or separately from one another, depending on the power demand. The module voltages U₁, U₂ do not add to the battery voltage U_{B} in this operating mode. The first and the second current sensor 16, 18 can measure very different currents depending on the switch position of the first and second switches S1, S2. In addition, only one battery module 12, 14 may be charged if, for example, a voltage difference between the two battery modules 12, 14 is too large and a very high equalizing current would otherwise flow.

For example, the first and the second battery module 12, 14 each have a module voltage U₁, U₂ of 400 V. The battery voltage U_{B} is then equal to 800 V in the first operating mode and equal to 400 V in the second operating mode. For example, when charging the battery system 100, if only 400 V is available at a charger, the second operating mode is required.

The battery system 100 also comprises a measurement electronics 30 comprising a first measurement channel 32, a second measurement channel 34, a third measurement channel 36 and a fourth measurement channel 38. The first measurement channel 32 is electrically connected to the first current sensor 16, while the second measurement channel 34 is electrically connected to the second current sensor 18. The third measurement channel 36 is electrically connected to a first temperature sensor for sensing the temperature of the first current sensor 16, while the fourth measurement channel 38 is electrically connected to a second temperature sensor for sensing the temperature of the second current sensor 18. The first and the second measurement channel 32, 34 are configured to measure the voltage at the respective current sensors 16, 18, which is converted into the current values of the current I_{M1}, I_{M2} flowing through the respective current sensors 16, 18. The third and the fourth measurement channel 36, 38 are configured to measure the voltage at the respective current sensors, which is converted into the current values of the respective current sensors 16, 18. The measurement electronics 30 comprises, for example, analog-to-digital converters (ADC) and discrete electronics. Preferably, the measurement electronics 30 is designed as an application-specific integrated circuit (ASIC).

For the sake of clarity of the representation of the battery system 100, further switches necessary for switching the battery system 100 between operating modes are not shown.

When performing the method proposed according to the invention, the battery system 100 operates in the first operating mode according to FIG. 1. In order to simplify the explanation, the method proposed according to the invention is explained below with reference to the example that the first and second current sensors 16, 18 are each designed as a current measuring resistor.

At the beginning, e.g., at the start of the trip, both current sensors 16, 18 have the same temperature and a current flows through them. The deviation of the two current sensors 16, 18 relative to one another at the same temperature is thus known.

Subsequently, a mean value Iₘₑₐₙ of the current of both current sensors 16, 18 and the deviation therefrom is determined.

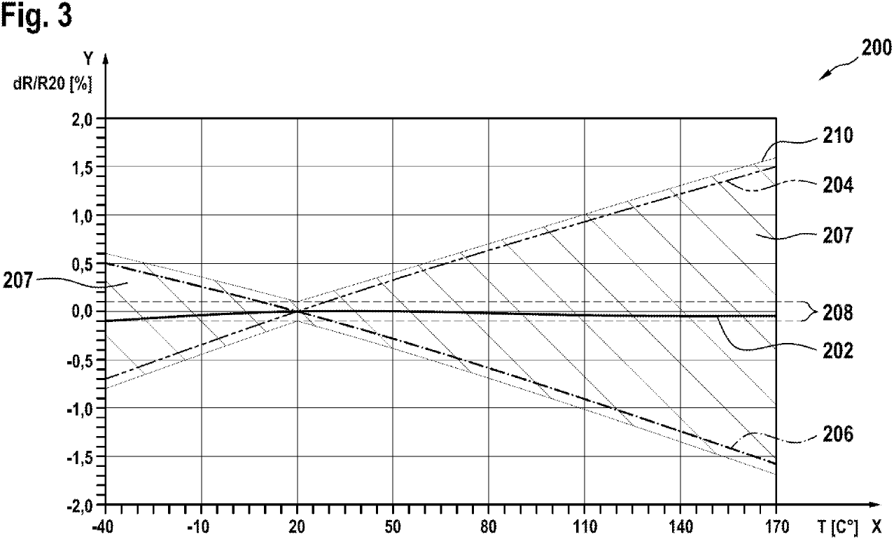

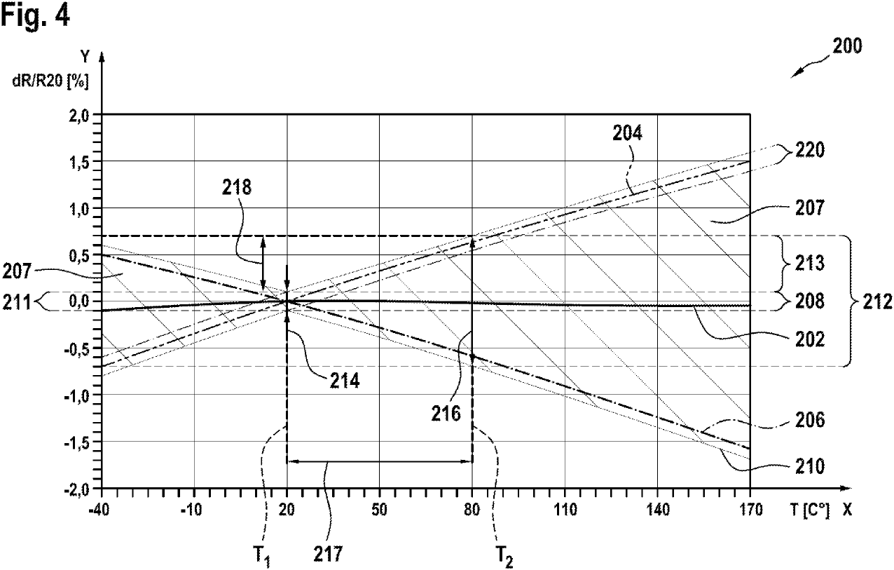

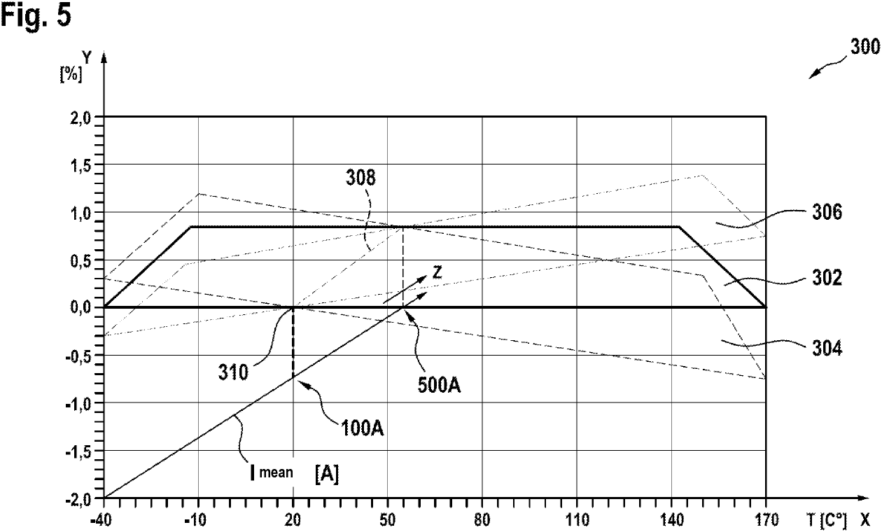

The two current sensors 16, 18 then heat up differently strongly and many further measurement points are created in a coordinate system (cf. FIG. 5). Due to the temperature difference 217 of the two current sensors 16, 18 connected in series and the knowledge that the same current always flows through the two current sensors 16, 18, the first current sensor 16 may, for example, have a value that deviates more strongly relative to the second current sensor 18, or vice versa, since they have different resistance values due to the different TCR curves and/or the temperature difference. This depends on how strongly the values change over the temperature, which is indicated in the TCR diagram (cf. FIGS. 3 and 4) with typical minimum and maximum values.

This deviation of both current sensors 16, 18 is sensed via the measuring device and a relative deviation between the current sensors 16, 18 is created depending on the current flow and indicates how much the current sensors 16, 18 deviate relative to one another at a particular temperature or, in the case of a current regression area, also from one another at a particular current.

With these values, the temperature-related error relative to one another, i.e., the relative error, can be determined later, i.e., after storing some values. In the process, a determination of the regression line slope is performed by means of many points in the coordinate system. This calibration works so well because many errors/drifts change slowly over the lifetime. In a calibration, it can therefore be assumed that all long-term errors are constant and the resulting deviation is primarily determined by the temperature difference.

FIG. 3 shows a schematic representation of a TCR diagram 200 of a current sensor 16, 18. On an X-axis of the TCR diagram 200, the temperature is plotted in [°C], while on a Y-axis of the TCR diagram 200, a resistance-value change rate dR/R20 is plotted in [%]. The resistance-value change rate corresponds to a change in the resistance value of the current sensor 16, 18 relative to a reference resistance value of the current sensor 16, 18. In the present case, a resistance value of the current sensor 16, 18 at a temperature of 20° C. is selected as the reference resistance value. However, a resistance value of the current sensor 16, 18 at another temperature may also be selected as the reference resistance value.

The TCR diagram shows a first TCR curve 202, a second TCR curve 204, and a third TCR curve 206. Here, the first TCR curve 202 corresponds to a typical or ideal resistance-value change/temperature curve of a current sensor 16, 18. The second and the third TCR curve 204, 206 each correspond to a resistance-value change/temperature curve of a worst case. For example, the second TCR curve 204 has a TCR of 100 ppm/°C, while the third TCR curve 206 has a TCR of -100 ppm/°C. The area between the second and the third TCR curve 204, 206 is referred to as the TCR tolerance range 207 of the current sensor 16, 18.

For example, while the values of the current sensors 16, 18 at the beginning of the lifetime are still close to the first TCR curve 202, the values deviate over the temperature, lifetime, accumulated temperature load and mechanical stress. As shown in FIG. 3, the resistance-value change rate of the current sensor 16, 18 at 20° C. is 0%.

Tolerance ranges of other components, such as the measurement electronics 30 as well as the temperature sensors, may be added to the TCR tolerance range 207 of the current sensor 16, 18. A range over the temperature that results from adding tolerance ranges of all components is referred to as overall tolerance range 210.

The measurement electronics 30 has a tolerance of, for example, ±0.1% over the lifetime and temperature. In the TCR diagram 200 shown in FIG. 3, this is referred to as a tolerance range 208 of the measurement electronics 30. At a temperature of 25° C., the tolerances of the measurement electronics 30 could also be well below 0.1%. For simpler clarification of the invention, a constant relative error is assumed since the absolute error of the measuring device is negligible at larger currents. In this example, the absolute error (offset error) is therefore not considered.

In the TCR diagram 200, the overall tolerance range 210 results from adding the tolerance 208 of the measurement electronics 30 to the TCR tolerance range 207 of the current sensor 16, 18. The overall tolerance range 210 may comprise the tolerance range of other components, such as the tolerance range of the temperature sensor.

FIG. 4 shows a schematic representation of the use of the TCR diagram 200 shown in FIG. 3 to perform the method proposed according to the invention. The method proposed according to the invention may be performed in any battery system 100 in which the current sensors 16, 18 are connectable or connected in series. For illustrating the invention, however, reference is made to the battery system 100 shown in FIG. 1 and FIG. 2.

The first and the second current sensor 16, 18 are connected in series when the method proposed according to the invention is performed. As a result, the same current flows through the first and the second current sensor 16, 18.

FIG. 4 shows that the first current sensor 16 is at a first temperature T₁ of 20° C. and the second current sensor 18 is at a second temperature T₂ of 80° C. A temperature difference 217 between the first and the second current sensor 16, 18, in the present case 60° C., may be generated by current only flowing through the second current sensor 18 when charging and both current sensors 16, 18 being connected in series after a certain period of time. It is also conceivable that the temperature difference 217 is generated by selecting different resistance values of the respective current sensors 16, 18.

The temperature difference 217 may be different. In other words, the method proposed according to the invention may also be performed at other temperatures or temperature differences.

FIG. 4 shows that the first current sensor 16 is at 20° C. and may deviate only by ±0.1% from the first TCR curve 202. In the present case, this deviation is illustrated by a first double arrow 214 and corresponds to a first overall tolerance range 211 of the first current sensor 16 at 20° C. or the tolerance range 208 of the measurement electronics 30.

FIG. 4 furthermore shows that the second current sensor 18 is at 80° C. and may deviate by ±0.7% from the first TCR curve 202. In the present case, this deviation is illustrated by a second double arrow 216 and corresponds to a second overall tolerance range 212 of the second current sensor 18 at 80° C.

The first and the second overall tolerance range 211, 212 of the first and the second current sensor 16, 18, may thus be used to calculate a calibratable tolerance range 213 for the second current sensor 18, which is illustrated by means of a third double arrow 218. In the present case, the calibratable tolerance range 213 results from subtracting the second overall tolerance range 212 from the first overall tolerance range 211 and is 0.6%. This completely eliminates the temperature-related error effect.

Since in the first operating mode of the battery system 100, the same current flows through the first and the second current sensor 16, 18, the temperature-related error (due to the individual TCR curve) of the second current sensor 18 can be calibrated and a deviation is calculated, which indicates how much the current sensors 16, 18 are apart relative to one another at particular temperatures. The temperature-related deviation between the current sensors 16, 18 can thus be determined.

If the TCR regression curve, which is shown in the present case as a TCR regression line for the sake of clarity of the representation and is also denoted by reference sign 204, is known, an individual TCR tolerance range 220 may be placed around the TCR regression line 204 depending on the accuracy of the measuring device. The same is also possible for the TCR regression curves of the other current sensors.

FIG. 5 shows a schematic representation of a conversion table 300, which is created when performing the method proposed according to the invention. This conversion table 300 respectively inter- and extrapolates a current- and temperature-dependent current regression area 304, 306 of all current sensors 16, 18 to be calibrated. Based thereon, the current- and temperature-related error of any current sensor 16, 18 may be calibrated with any other current sensor.

For illustrating the invention, reference is also made here to the battery system 100 shown in FIG. 1 and FIG. 2. Accordingly, the assumptions for FIG. 4 also apply thereto.

FIG. 5 shows that the conversion table 300 is shown in a three-dimensional coordinate system having an X-axis, a Y-axis, and a Z-axis. The temperature in [°C] is plotted on the X-axis. On the Z-axis, an averaged current value Iₘₑₐₙ of both current sensors 16, 18 in [A] is plotted. On the Y-axis, a change rate/deviation from the ideal value in [%] of an intersection line 308 of the current regression areas 304, 306, which in a first approximation is equal to the intersection point 310 (i.e., the resistance-value change rate dR/R20 is zero), is plotted.

Additionally, the conversion table 300 shown in FIG. 5 may have a t-axis on which the time or timestamp of the measurements is plotted.

During the creation of the conversion table 300, the initial values of the respective current sensors 16, 18, e.g., the default values or predetermined standard values of the current sensors 16, 18, are first entered into the conversion table 300. If the battery system 100 is used in a vehicle, this may occur at 0-km of the vehicle.

The sensed temperature values and current values of the respective current sensors 16, 18 are subsequently determined at different temperatures and currents. Timestamps of the acquisitions are preferably also determined at different temperatures and currents.

Averaged current values Iₘₑₐₙ are calculated. When performing the method proposed according to the invention, the first current sensor 16 measures the first current I_{M1} (cf. FIG. 1) at the temperature T₁ (cf. FIG. 4), and the second current sensor 18 measures the second current I_{M2} (cf. FIG. 1) at the temperature T₂ (cf. FIG. 4) at the same time.

An averaged current value is calculated as follows:

$${\text{I}}_{\text{mean}} = \left({\text{I}}_{\text{M1}} + {\text{I}}_{\text{M2}}\right) / 2$$

This creates two points: a first point P₁ (Iₘₑₐₙ, T₁) and a second point P₂ (Iₘₑₐₙ, T₂).

These points are stored in the coordinate system. This process is repeated until some points are stored over a temperature range of, for example, at least 30° C. The more data are acquired, the more accurately the temperature-related error can be eliminated.

In the coordinate system with many accumulated data, there is an averaged current value of the two current sensors 16, 18 at every temperature value.

In this case, measurement points that are dependent on the temperature of the respective current sensors 16, 18 and the deviations of the current values sensed by the respective current sensors 16, 18 relative to one another are used to calculate a first current regression area 304 for the first current sensor 16 and a second current regression area 306 for the second current sensor 18.

An averaged current regression area 302 may also be calculated, which is introduced for illustrating the invention and is precisely the mean value of the current regression areas of the current sensors 16, 18. The averaged current regression area 302 is thus the reference, and the deviation relative thereto is determined with the first and the second current regression area 304, 306. For example, at 80° C., the first current sensor 16 deviates by -0.3%, while the second current sensor 18 deviates by +0.3% from the reference value.

For each measurement point, e.g., P₁ and P₂, a percent error can be calculated by means of a quotient of actually measured current and the deviation relative to the averaged current value Iₘₑₐₙ. As a result, relative temperature-dependent deviations of the respective current sensors 16, 18 relative to one another and/or relative to the averaged current regression area 302, which is an artificially created reference area, are known.

Thereafter, a TCR regression curve for the respective current sensors 16, 18 is calculated based on a deviation of the respective current regression area 304, 306 relative to one another and/or relative to the averaged current regression area 302 and a temperature difference 217 between the current sensors 16, 18. In other words, one or more measurement points are recorded and a current regression area 304, 306 is calculated for the respective current sensors 16, 18. By means of the intersection line 308 of the current regression area 304, 306, a statement about the absolute temperature-related deviation can be made, wherein the intersection line 308 can be considered approximately as intersection point 310 since the current sensors 16, 18 are trimmed to this temperature (generally 20° C.) and the resistance-value change rate is zero here. In some circumstances, it may be sufficient to calculate a single correction factor per current sensor by means of different temperature values at the respective current sensors 16, 18. In this case, the TCR regression area or TCR regression curve becomes a TCR regression line. The correction factor corresponds to the slope of the TCR regression line.

Since all TCR curves at, for example, 20° C. and 0A have a temperature- and current-dependent change rate of zero, it is necessary if there are no measured values at temperatures around 20° C. and 0A, that the measurement points of both are extrapolated in order to determine the “y-intercept” in this way (measured error at 20° C. and 0A). This intersection point 310 of the current regression area 304, 306 of the first and the second current sensor 16, 18 gives the two current sensors an absolute value, i.e., no longer relative to one another or relative to the reference area.

The conversion table 300 and the current regression areas 304, 306 are constantly updated. In the process, older values, e.g., of more than 6 months, can automatically be removed from the conversion table 300 and be replaced by the newer values.

A plausibility check is furthermore constantly carried out as to whether the temperature- and current-dependent current regression areas 304, 306 of the respective current sensors 16, 18 is in the overall tolerance range 210 and/or in the individual TCR tolerance range 220. In the event of a permanent deviation, countermeasures may be initiated, such as an inspection in the workshop.

The invention is not limited to the exemplary embodiments described herein and the aspects highlighted therein. Rather, a variety of modifications, which are within the scope of activities of the person skilled in the art, is possible within the range specified by the claims.

1. A method for calibrating a plurality of current sensors (16, 18) connected in series, the method comprising the steps of:
determining a temperature difference (217) between the current sensors (16, 18);
sensing temperature values and current values of the respective current sensors (16, 18) at different temperatures and currents;
calculating averaged current values (Iₘₑₐₙ) of two current sensors (16, 18) based on the current measured values sensed by the respective current sensors (16, 18);
calculating a current regression area (304, 306) for the respective current sensors (16, 18) through measurement points that are dependent on the temperature of the respective current sensors (16, 18) and the deviation of the current values sensed by the respective current sensors (16, 18) relative to one another; and
calculating a TCR regression curve or a TCR regression area for the respective current sensors (16, 18) based on a deviation and an intersection curve (308) of the respective current regression areas (304, 306) relative to one another and/or relative to an averaged current regression area (302) and a temperature difference (217) between the current sensors (16, 18).

2. The method according to claim 1, wherein
timestamps of the temperature and current measurements are captured at different temperatures and currents.

3. The method according to claim 1, wherein
an individual TCR tolerance range (220), in which the TCR regression curve of the respective current sensors (16, 18) lies, is calculated for the respective current sensors (16, 18).

4. The method according to claim 1, wherein
a conversion table (300) for the current measurements is created with the following steps:
entering initial values of the respective current sensors (16, 18) into the conversion table (300);
determining the sensed temperature values and current values of the respective current sensors (16, 18) as well as, where appropriate, the captured timestamps at different temperatures and currents;
updating the conversion table (300) and the TCR regression curves and current regression areas (304, 306); and
plausibility checking whether a temperature-dependent error of the respective current sensors (16, 18) is in an overall tolerance range (210).

5. The method according to claim 4, wherein
old data acquired based on measurements and/or calculations are overwritten.

6. The method according to claim 1, wherein
one of the current sensors (16, 18) is selected as a reference sensor, which is used to calibrate all the other current sensors (16, 18).

7. The method according to claim 1, wherein
quality characteristics of the respective current sensors (16, 18) are evaluated by means of cloud-controlled artificial intelligence.

8. A battery system (100) comprising a plurality of current sensors (16, 18) that are connected in series and a computer configured to:
determine a temperature difference (217) between the current sensors (16, 18);
determine temperature values and current values of the respective current sensors (16, 18) at different temperatures and currents;
calculate averaged current values (Iₘₑₐₙ) of two current sensors (16, 18) based on the current measured values sensed by the respective current sensors (16, 18);
calculate a current regression area (304, 306) for the respective current sensors (16, 18) through measurement points that are dependent on the temperature of the respective current sensors (16, 18) and the deviation of the current values sensed by the respective current sensors (16, 18) relative to one another; and
calculate a TCR regression curve or a TCR regression area for the respective current sensors (16, 18) based on a deviation and an intersection curve (308) of the respective current regression areas (304, 306) relative to one another and/or relative to an averaged current regression area (302) and a temperature difference (217) between the current sensors (16, 18).

9. The battery system (100) according to claim 8, wherein
the current sensors (16, 18) are thermally decoupled from one another.

10. The battery system (100) according to claim 8, wherein
the current sensors (16, 18) have different resistance values.

11. A vehicle comprising a battery system (100) according to claim 8.
